(19) United States
(12) Patent Application Publication
(10) Pub. No.: US 2026/0314427 A1
(43) Pub. Date: Oct. 8, 2026

(54) PENETRATION DETECTION SENSOR

(71) Applicant: Mercury Systems, Inc., Andover, MA (US)

(72) Inventors: Michael Francis Shorey, Carlisle, MA (US); Roy Alan Bolduc, Salisbury, MA (US); Jonathon David Mellott, Gainesville, FL (US); Daniel James Toohey, South Grafton, MA (US); Tony Trinh, Queen Creek, AZ (US)

(21) Appl. No.: 19/169,888

(22) Filed: Apr. 3, 2025

(51) Int. Cl. H01L 23/00; B82Y 35/00; G01N 27/04

(52) U.S. Cl. CPC H10W 42/40; B82Y 35/00; G01N 27/041

(57) ABSTRACT

Devices, methods, and techniques for a hole detection sensor are provided. In one aspect, a hole detection sensor includes a sensing layer including a plurality of boron nitride nanotubes (BNNTs); and a plurality of electrode pads being arranged along a perimeter of the sensing layer. The electrode pads are coupled to the sensing layer. The sensor is configured to, using at least two of the plurality of electrode pads, generate an electrical signal corresponding to an impedance value of the sensing layer. The impedance value is indicative of a structural integrity condition of the sensing layer.

### TECHNICAL FIELD

The present disclosure relates to a tamper-proofing system.

### BACKGROUND

A tampering-proof system can be used to detect a tampering event and protect a device (e.g., a chip) from physical attacks or authorized access. When a breach occurs, such as an attempt to destroy the device, the tampering-proof system can detect a disruption or physical damages of a structure, triggering an alert or protective response. The tampering-proof system can be used in military, financial or supply chain security environments.

### SUMMARY

The present disclosure describes methods, devices, and techniques for a penetration detection sensor (also called a hole detection sensor in the present disclosure) configured to detect a penetration through a sensing layer to improve a tampering protection of a chip that is attached to the sensor.

In general, one aspect of the subject matter described in this specification can be implemented in a hole detection sensor that includes a sensing layer including a plurality of boron nitride nanotubes (BNNTs); and a plurality of electrode pads being arranged along a perimeter of the sensing layer and coupled to the sensing layer. The sensor is configured to, using at least two of the plurality of electrode pads, generate an electrical signal corresponding to an impedance value of the sensing layer. The impedance value is indicative of a structural integrity condition of the sensing layer.

The foregoing and other implementations can each optionally include one or more of the following features, alone or in combination. In some implementations, the sensing layer includes a plurality of carbon nanotubes (CNTs).

In some implementations, the sensing layer includes conductive dopants.

In some implementations, the plurality of BNNTs are arranged in at least one BNNT layer, the plurality of CNTs are arranged in at least one CNT layer, and the at least one BNNT layer and the at least one CNT layer are encapsulated in an encapsulant layer.

In some implementations, the at least one BNNT layer and the at least one CNT layer alternate with one another in the encapsulant layer.

In some implementations, the perimeter of the sensing layer includes a plurality of edges, the plurality of edges including a first edge, a second edge, a third edge and a fourth edge, the first edge and the third edge being opposed to each other along a first direction, the second edge and the fourth edge being opposed to each other along a second direction. The plurality of electrode pads are along the first to fourth edges of the perimeter of the sensing layer.

In some implementations, the structural integrity condition includes at least one of a presence of a hole extending into the sensing layer, a crack, a mechanical strain, or a mechanical stress.

In some implementations, the sensor includes: a wiring board; and one or more contacts on a first side of the wiring board, the one or more contacts being coupled to the plurality of electrode pads. The sensing layer and the plurality of electrode pads are on a second side of the wiring board that is opposite to the first side.

In some implementations, the sensing layer is on the plurality of electrode pads.

In some implementations, the second side of the wiring board includes an inner region and a perimeter region that surrounds the inner region. The inner region includes a cavity, the sensing layer is inside the cavity and encapsulated within an encapsulant layer, and the plurality of electrode pads are on the perimeter region and surround the sensing layer.

In some implementations, the encapsulant layer encapsulates a structure inside the cavity.

In some implementations, the structure includes a chip or a conductor.

In some implementations, the sensing layer is a first sensing layer. The sensor includes a second sensing layer, the second sensing layer including a plurality of BNNTs, the second sensing layer covering both the first sensing layer and the plurality of electrode pads, the plurality of electrode pads being coupled to the second sensing layer.

In some implementations, the wiring board includes an interconnecting layer, and the plurality of electrode pads are coupled to the one or more contacts through the interconnecting layer.

In some implementations, the interconnecting layer includes at least one via and at least one metal trace.

In some implementations, the one or more contacts include one or more solder balls, one or more micro-bumps, one or more bonding pads, or one or more copper pillars.

In some implementations, the sensor is configured to generate the electrical signal using a first electrode pad and a second electrode pad of the plurality of electrode pads. The perimeter includes a plurality of edges, the first electrode pad is adjacent to a first edge of the perimeter, the second electrode pad is adjacent to a second edge of the perimeter, and the first edge is perpendicular to the second edge.

In some implementations, the sensor is configured to generate a plurality of electrical signals that includes the electric signal, each of the plurality of electrical signals is associated with an impedance value of a respective portion of the sensing layer. The sensor is configured to transmit, through the one or more contacts, the plurality of electrical signals to a chip.

Another aspect of the subject matter described in this specification can be implemented in a hole detection sensor that includes a wiring board having one or more contacts on a first side of the wiring board; a sensing layer on a second side of the wiring board that is opposite to the first side; and a plurality of electrode pads on the second side of the wiring board, the plurality of electrode pads being arranged along a perimeter of the sensing layer and coupled to the sensing layer. The sensor is configured to, using at least two of the plurality of electrode pads, generate an electrical signal corresponding to an impedance value of the sensing layer. The impedance value is indicative of a structural integrity condition of the sensing layer.

The foregoing and other implementations can each optionally include one or more of the following features, alone or in combination. In some implementations, the sensing layer includes a plurality of boron nitride nanotubes (BNNTs).

In some implementations, the sensing layer includes a plurality of carbon nanotubes (CNTs).

In some implementations, the sensing layer includes conductive dopants.

In some implementations, the plurality of BNNTs are arranged in at least one BNNT layer, and the plurality of CNTs are arranged in at least one CNT layer.

In some implementations, the at least one BNNT layer and the at least one CNT layer alternate with one another.

In some implementations, the sensing layer is encapsulated in an encapsulant layer.

In some implementations, the structural integrity condition includes at least one of a presence of a hole extending into the sensing layer, a crack, a mechanical strain, or a mechanical stress.

In some implementations, the sensing layer is on the plurality of electrode pads.

In some implementations, the second side of the wiring board includes an inner region and a perimeter region that surrounds the inner region. The inner region includes a cavity, the sensing layer is inside the cavity, and the plurality of electrode pads are on the perimeter region and surround the sensing layer.

In some implementations, the sensing layer encapsulates a structure inside the cavity.

In some implementations, the structure includes a chip or a conductor.

In some implementations, the sensing layer is a first sensing layer. The sensor includes a second sensing layer, the second sensing layer including a plurality of BNNTs, the second sensing layer covering both the first sensing layer and the plurality of electrode pads, the plurality of electrode pads being coupled to the second sensing layer.

In some implementations, the wiring board includes an interconnecting layer, and the plurality of electrode pads are coupled to the one or more contacts through the interconnecting layer.

In some implementations, the interconnecting layer includes at least one via and at least one metal trace.

In some implementations, the one or more contacts include one or more solder balls, one or more micro-bumps, one or more bonding pads, or one or more copper pillars.

In some implementations, the sensor is configured to generate the electrical signal using a first electrode pad and a second electrode pad of the plurality of electrode pads, and the perimeter includes a plurality of edges, the first electrode pad is in contact with a first edge of the perimeter, the second electrode pad is contact with a second edge of the perimeter, and the first edge is perpendicular to the second edge.

In some implementations, the sensor is configured to generate a plurality of electrical signals that includes the electric signal, each of the plurality of electrical signals is associated with an impedance value of a respective portion of the sensing layer, and the sensor is configured to transmit, through the one or more contacts, the plurality of electrical signals to a chip.

Another aspect of the subject matter described in this specification can be implemented in a hole detection device that includes a sensor including: a sensing layer; and a plurality of electrode pads being arranged along a perimeter of the sensing layer and coupled to the sensing layer. The sensor is configured to, using at least two of the plurality of electrode pads, generate an electrical signal corresponding to an impedance value of the sensing layer. The hole detection device includes a chip stacked with the sensor. The chip is configured to receive the electrical signal from the sensor and determine, based on the electrical signal, a presence of a hole in the sensing layer.

The foregoing and other implementations can each optionally include one or more of the following features, alone or in combination. In some implementations, the sensor includes a plurality of boron nitride nanotubes (BNNTs).

In some implementations, the sensor includes: a wiring board; and one or more first contacts on a first side of the wiring board, the one or more first contacts being coupled to the plurality of electrode pads. The sensing layer and the plurality of electrode pads are on a second side of the wiring board that is opposite to the first side.

In some implementations, the chip includes one or more second contacts, and at least one of the one or more second contacts are in contact with a corresponding first contact of the one or more first contacts.

In some implementations, the sensor is configured to generate a plurality of electrical signals that includes the electric signal, each of the plurality of electrical signals is associated with an impedance value of a respective portion of the sensing layer. The sensor is configured to transmit, through the one or more first contacts and the one or more second contacts, the plurality of electrical signals to the chip. The chip is configured to determine, based on the plurality of electrical signals, the presence of the hole in the sensing layer.

In some implementations, the chip includes at least one processor; and one or more memories coupled to the at least one processor and storing programming instructions for execution by the at least one processor to perform operations including: estimating the impedance value of the sensing layer; and compare the estimated impedance values with a reference value.

In some implementations, the operations include: based on the estimated impedance value being above the reference value, determining the presence of the hole in the sensing layer; and based on the estimated impedance value being below the reference value, determining an absence of the hole in the sensing layer.

Another aspect of the subject matter described in this specification can be implemented in a method that includes the actions of: providing a wiring board; forming one or more contacts on a first side of the wiring board; forming a sensing layer including a plurality of boron nitride nanotubes (BNNTs), the sensing layer being on a second side of the wiring board that is opposed to the first side; and forming a plurality of electrode pads on the second side of the wiring board, the plurality of electrode pads being arranged along a perimeter of the sensing layer and coupled to the sensing layer.

The foregoing and other implementations can each optionally include one or more of the following features, alone or in combination. In some implementations, the sensing layer includes a plurality of carbon nanotubes (CNTs). Forming the sensing layer includes: encapsulating at least one CNT layer and at least one BNNT layer into a polymer layer, the at least one CNT layers including the plurality of CNTs, and the at least one BNNT including the plurality of BNNTs.

In some implementations, the at least one CNT layer and the at least one BNNT layer alternate with one another.

In some implementations, forming the sensing layer includes: implanting conductive dopants into the sensing layer.

Another aspect of the subject matter described in this specification can be implemented in a method that includes the actions of: providing a sensor, the sensor including a sensing layer and a plurality of electrode pads being arranged along a perimeter of the sensing layer; providing a chip coupled to the sensor; generating a first electrical signal, using a first pair of the plurality of electrode pads, the first electrical signal corresponding to an impedance value of a first portion of the sensing layer; transmitting the first electrical signal to the chip; and determining, by the chip and based on the first electrical signal, a presence of a hole in the sensing layer.

The foregoing and other implementations can each optionally include one or more of the following features, alone or in combination. In some implementations, the method includes generating a second electrical signal, using a second pair of the plurality of electrode pads, the second electrical signal corresponding to an impedance value of a second portion of the sensing layer. Determining the presence of the hole in the sensing layer includes: determining the presence of the hole in the sensing layer based on the first electrical signal and the second electrical signal.

In some implementations, the first pair of the plurality of electrode pads includes a first electrode pad and a second electrode pad. The perimeter includes a plurality of edges, the first electrode pad is in contact with a first edge of the perimeter, the second electrode pad is contact with a second edge of the perimeter, and the first edge is perpendicular to the second edge.

In some implementations, transmitting the first electrical signal to the chip includes: transmitting the first electrical signal to the chip through one or more contacts of the sensor, the one or more contacts being on a first side of a wiring board of the sensor, the sensing layer and the plurality of electrode pads being on a second side of the wiring board that is opposite to the first side, the plurality of electrode pads being coupled to the one or more contacts.

In some implementations, the method includes estimating, by the chip and based on the first electrical signal, the impedance value of the first portion of the sensing layer; and comparing the estimated impedance value with a reference value.

In some implementations, the method includes based on the estimated impedance value being above the reference value, determining, by the chip, the presence of the hole in the sensing layer; and based on the estimated impedance value being below the reference value, determining, by the chip, an absence of the hole in the sensing layer.

Particular embodiments of the subject matter described in this specification can be implemented so as to realize one or more of the following advantages. For example, the techniques described in the present disclosure can enhance a performance of the hole detection sensor by using boron nitride nanotubes (BNNTs). In some implementations, a sensing layer in the hole detection sensor includes BNNTs. The sensing layer can further include additional dopants or carbon nanotubes (CNTs). BNNTs may exhibit good thermal stability and high thermal conductivity. Therefore, integrating BNNTs with CNTs may improve the durability of the sensor under extreme conditions, making the hole detection features more robust against thermal-based tampering attempts. Further, BNNTs may possess high mechanical strength. This can enhance the structural integrity of the sensing layer, providing additional resistance to physical tampering. Additionally, BNNTs are electrical insulators with a wide bandgap (about 5.7 eV). Incorporating BNNTs can provide localized electrical insulation within the sensing layer, potentially allowing for more complex sensor architectures that can detect a broader range of tampering methods.

In addition, the techniques enable a detection of penetration from any direction in a three-dimensional (3D) space. For example, in some implementations, the sensing layer can be used a protective layer for the chip by encapsulating the chip onto a wiring board. When a tampering event occurs, such as an attempt to puncture or destroy the chip, a hole may be formed that penetrates the sensing layer before reaching the encapsulated chip. The hole detection sensor can detect this tampering event by measuring changes in the impedance of the sensing layer. By encapsulating the chip with the sensing layer on at least two sides, the hole detection sensor can detect holes penetrating from multiple directions.

Further, the techniques allow for determining a size or location of the hole in the sensing layer. For example, in some implementations, the hole detection sensor includes multiple electrode pads that can be arranged around the sensing layer in at least two directions. By using different pairs of the electrode pads, impedance values of different portions of the sensing layer can be measured. This allows for triangulating a location of the hole in the sensing layer based on the impedance values and locations of the corresponding electrode pads.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates an exploded view of an example of a hole detection sensor.

FIG. 1B illustrates a plan view of a first side of the hole detection sensor of FIG. 1A.

FIG. 1C illustrates a plan view of a second side of the hole detection sensor of FIG. 1A.

FIG. 2 illustrates a side view of an example of a sensing layer.

FIGS. 3A and 3B illustrate another example of a hole detection sensor.

FIG. 3C illustrates an example of a wiring board with cavities.

FIG. 3D illustrates examples of holes in the hole detection sensor of FIG. 3A.

FIG. 4A illustrates an exploded view of yet another example of a hole detection sensor.

FIG. 4B illustrates an assembled view of the hole detection sensor of FIG. 4A.

FIG. 5 illustrates an example of a device with a hole detection sensor stacked on a chip.

FIG. 6 illustrates a flow chart of an example of a method of detecting a hole using a device.

FIG. 7 illustrates a flow chart of an example of a method of manufacturing a hole detection sensor.

It is to be understood that the various exemplary implementations shown in the figures are merely illustrative representations and are not necessarily drawn to scale.

### DETAILED DESCRIPTION

The present disclosure describes a hole detection sensor configured to detect a hole that extends into or penetrates the sensor. The hole detection sensor can either encapsulate or be stacked on a target chip as a protective layer. In cases of an unauthorized access, reverse engineering, or physical attack on the target chip, the hole detection sensor may be destroyed first (e.g., being punctured). By detecting the presence of the hole, the hole detection sensor can promptly identify a potential tampering event. Such detection may allow for the target chip to erase sensitive data or disable its functionality. In some implementations, the hole detection sensor includes a sensing layer and multiple electrode pads that are arranged around the sensing layer. The sensing layer can include carbon nanotubes (CNTs) and boron nitride nanotubes (BNNTs), or BNNTs with dopants. The sensing layer can be encapsulated inside a polymer layer. The resulting layer can then encapsulate the target chip onto a printed wiring board (PWB). In a tampering event, a hole may be created that penetrates at least the sensing layer. The sensor can detect, through the multiple electrode pads, a change of impedance of the sensing layer. The sensor can then transmit an electrical signal corresponding to the change of the impedance to the target chip or another chip. The electrical signal can be used to detect the presence of the hole or to determine parameters of the hole.

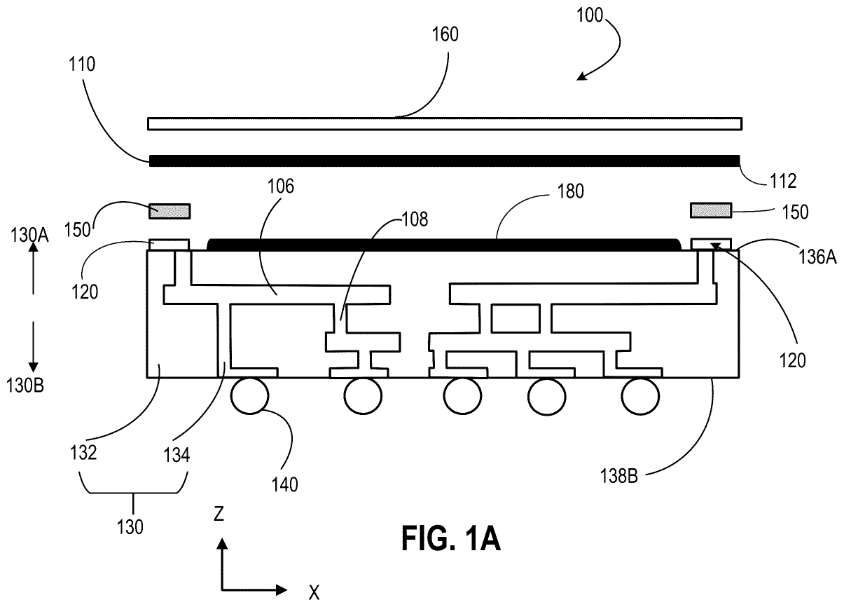

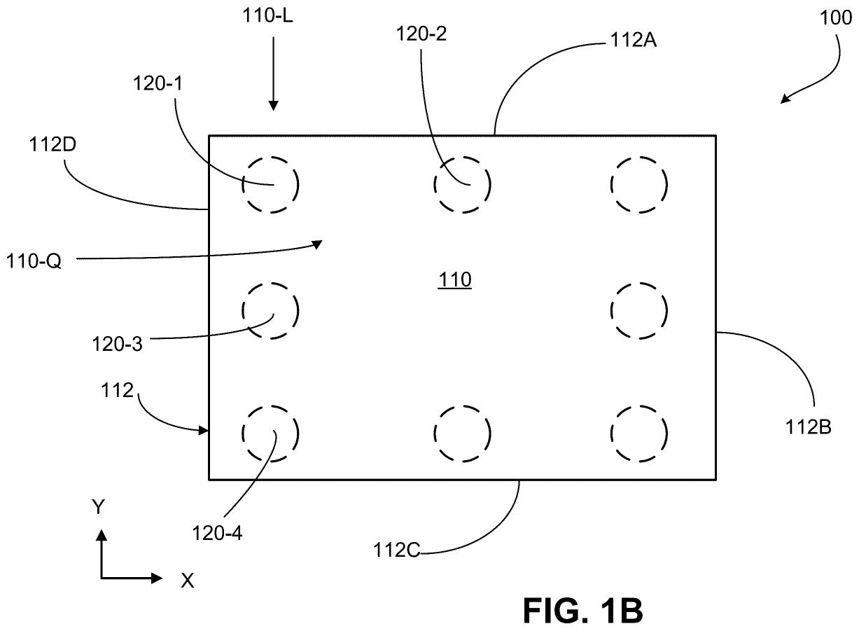

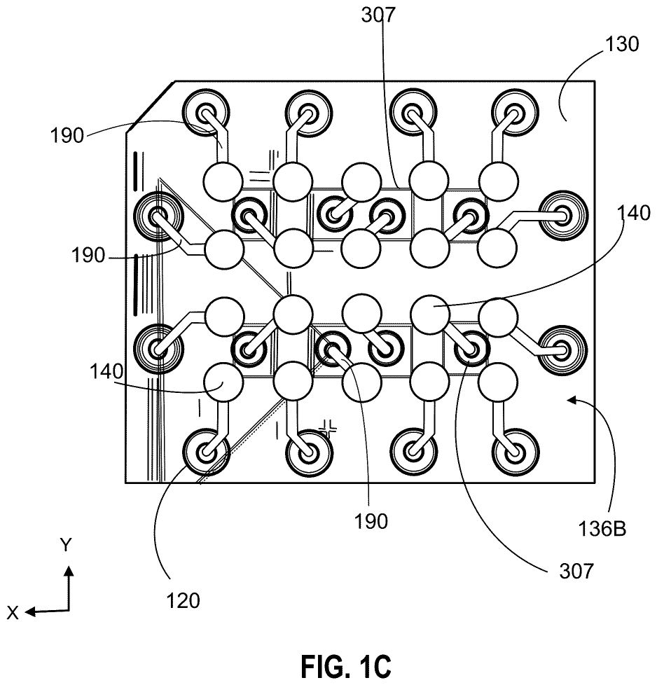

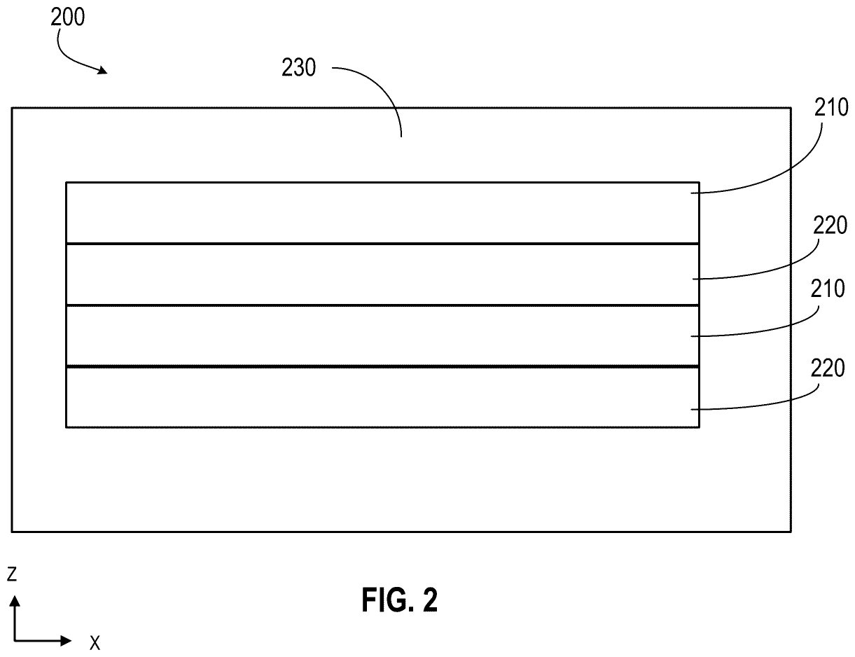

FIG. 1A illustrates an exploded view of an example of a hole detection sensor 100. FIG. 1B illustrates a plan view of a first side of the hole detection sensor 100. FIG. 1C illustrates a plan view of a second side of the hole detection sensor 100. FIG. 2 illustrates a side view of an example of a sensing layer. For ease of description, reference will be made to FIGS. 1A-2 when describing the structure of the hole detection sensor 100. As used herein, whether one component (e.g., a layer, a structure, or a device) is “on,” “above,” or “below” another component (e.g., a layer, a structure or a device) of a hole detection sensor is determined relative to a second surface 136B of a wiring board 130 in the z-direction (i.e., the vertical direction perpendicular to the second surface 136B of the wiring board 130), when the second surface 136B of the wiring board 130 faces downward, and a first surface 136A of the wiring board 130 faces upward.

As shown in FIG. 1A, the hole detection sensor 100 includes a sensing layer 110, a plurality of electrode pads 120, a wiring board 130, and one or more contacts 140 on the wiring board 130. The sensing layer 110 and the electrode pads 120 can be on a first side 130A of the wiring board 130, while the one or more contacts 140 can be on a second side 130B of the wiring board 130. The second side 130B can be opposed to the first side 130A along a vertical direction (e.g., Z direction).

In some implementations, the sensing layer 110 includes multiple CNTs. For example, the sensing layer 110 can be a CNT sheet layer. In some implementations, the sensing layer 110 includes multiple BNNTs with dopants. For example, the sensing layer 110 can be a doped BNNT sheet layer. The dopants can be conductive or semi-conductive (e.g., silicon, iron, cobalt, nickel, molybdenum, titanium, and/or lithium). The doped BNNTs may have enhanced electrical conductivity.

In some implementations, the sensing layer 110 includes both BNNTs and CNTs. Without being bound to any particular theory, BNNTs may exhibit good mechanical strength, thermal stability, and high thermal conductivity, while CNTs may provide good electrical conductivity. Turning briefly to FIG. 2, in some implementations, the BNNTs can be arranged in at least one BNNT layer 210, and the CNTs can be arranged in at least one CNT layer 220. The at least one BNNT layer 210 and the at least one CNT layer 220 can be encapsulated in an encapsulant layer 230 in an alternative matter (e.g., alternating along Z direction). This sensing layer 200 can be positioned on the wiring board (e.g., 130 of FIG. 1A) along the Z direction. The encapsulant layer 230 can include epoxy resins, silicones, polyurethane (PU), polyimides, or any other suitable materials. These alternating layers of CNTs and BNNTs may provide tailored electrical and mechanical properties. For instance, a BNNT layer 210 can serve as an insulating barrier, while a CNT layer 220 can function as the sensing element.

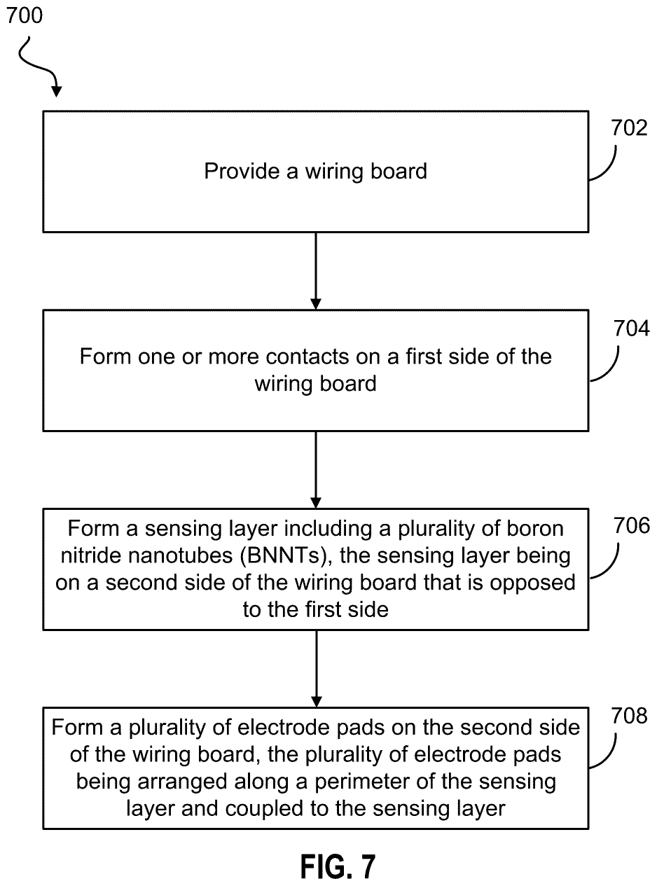

In some implementations, as described with greater details below in reference to FIG. 7, the surfaces of CNT layers 220 and BNNT layers 210 can be functionalized to promote better interfacial bonding with one another and/or with the encapsulant 230.

In some implementations, instead of having clear separation or layering between the CNTs and BNNTs, the CNTs and BNNTs can be scattered throughout the encapsulant layer 230. For example, both CNTs and BNNTs can be dispersed within the encapsulant layer 230, forming a hybrid composite. This hybrid composite can have homogenously mixed CNTs and BNNTs.

Without being bound to any particular theory, integrating BNNTs with CNTs may offer complementary properties that enhance the performance of the hole detection sensor 100. For example, BNNTs are electrical insulators with a wide bandgap (about 5.7 eV). Incorporating BNNTs can provide localized electrical insulation within the composite, potentially allowing for more complex sensor architectures that can detect a broader range of tampering methods. Additionally, BNNTs may exhibit high thermal stability. This can improve the durability of the sensor under extreme conditions, making the hole detection features more robust against thermal-based tampering attempts. Further, BNNTs may possess high mechanical strength, which can enhance the structural integrity of the sensing layer, providing additional resistance to physical tampering. Therefore, by integrating BNNTs with CNTs, the hole detection sensor 100 can have enhanced mechanical strength and thermal stability.

The impedance value of the sensing layer 110, 200 can change under conditions of strain, stress, crack, hole, or any other physical deformation. The impedance value can include an electrical resistance value, a capacitance value, and/or an inductance value. Without being bound to any particular theory, when the sensing layer 110, 200 is subject to strain, stress, cracks or holes, the doped BNNTs and/or CNTs may deform or stretch. This deformation may alter the electrical conductivity of the sensing layer 110, 200, resulting in a change of the impedance. Therefore, the hole detection sensor 100 can detect strain, stress, cracks, or holes based on the changes of the impedance value of the sensing layer 110, 200. The hole may penetrate completely through the sensing layer 110, 200 or extend partially into the sensing layer 110, 200.

Returning to FIG. 1A, the electrode pads 120 can be positioned below the sensing layer 110 and electrically connected to the sensing layer 110 via direct contact with the sensing layer 110 or through an intermediate medium such as solder or conductive epoxy 150. The sensing layer 110 may be metalized to facilitate the connection to the electrode pads 120. The electrode pads 120 can include a conductive material, including without limitation to, copper, copper alloy, aluminum, nickel, silver or gold. In some implementations, the electrode pads 120 include electroless nickel immersion gold (ENiG) plated pads. The electrode pads 120 can be in any suitable shape. For example, the electrode pads 120 can have a circular shape (as shown in FIG. 1B), an elliptical shape, a square shape, or a rectangular shape. In some implementations, each electrode pad 120 has a width or diameter between 0.5 mm and 5 mm, between 2 mm and 7 mm, between 3 mm and 10 mm, or between 5 mm and 15 mm.

In some implementations, the electrode pads 120 are in direct contact with the CNTs or doped BNNTs in the sensing layer 110. In some implementations, as shown in FIG. 1A, the electrode pads 120 are coupled to the sensing layer 110 through a solder structure 150. The solder structure 150 can be a conductive structure (e.g., copper) and have a size or arrangement similar to that of the electrode pads 120. By electrically connecting with the sensing layer 110, the electrode pads 120 can be used to measure an impedance value of the sensing layer 110. As noted above, the impedance value is indicative of a structural integrity condition of the sensing layer 110. The structural integrity condition includes at least one of a presence of a hole extending into the sensing layer 110, a crack, a mechanical strain, or a mechanical stress.

Referring now to FIG. 1B, in plan view, the sensing layer 110 can have a rectangular shape, but is not limited thereto. The sensing layer 110 can have any other regular shape (e.g., a square shape, a hexagonal shape, an octagonal shape), or irregular shape. The perimeter 112 of the sensing layer 110 can include a plurality of edges. In the present example, the perimeter 112 includes a first edge 112A, a second edge 112B, a third edge 112C and a fourth edge 112D. The first edge 112A and the third edge 112C can be opposed to each other along Y direction, while the second edge 112B and the fourth edge 112D can be opposed to each other along X direction. It is to be noted that the number of edges of the perimeter 112 can vary based on the shape of the sensing layer 110.

Multiple electrode pads 120 can be arranged adjacent to the perimeter 112 of the sensing layer 110. The electrode pads 120 can be arranged along each of the first to fourth edges 112A-112D to form a matrix pattern. The electrode pad matrix can be parallel to the first to fourth edges 112A-112D of the sensing layer 110 with substantially equal distance between adjacent electrode pads 120 along each edge. While the example implementation in FIG. 1B illustrates three electrode pads 120 along each edge, other numbers of the electrode pads 120 are also possible. In some implementations, at least one of the electrode pads 120 is connected to a ground voltage level (e.g., 0V).

The matrix arrangement of the electrode pads 120 may allow for the measurement of the impedance value across different portions of the sensing layer 110. For example, by using the first electrode pad 120-1 and the fourth electrode pad 120-4, an impedance value of a left portion 110-L of the sensing layer 110 can be measured. In another example, by using the second electrode pad 120-2 and the third electrode pad 120-3, an impedance value of an upper-left quadrant 110-Q of the sensing layer 110 can be measured. Therefore, by using different pairs of the electrode pads 120, the impedance value of different portions of the sensing layer 110 can be determined. This allows for triangulating a location of the penetration or hole in the sensing layer 110 based on the measured impedance values and locations of the corresponding electrode pads 120.

Returning to FIG. 1A, the wiring board 130 can include a base structure 132. The wiring board 130 can be referred to as a PWB or a printed circuit board (PCB) in some cases. The base structure 132 can include a non-conductive material, e.g., epoxy region, or fiberglass. The base structure 132 can be relatively rigid to provide mechanical support to the sensing layer 110 and the electrode pads 120. The base structure 132 can have a first surface 136A and a second surface 136B opposed to the first surface 136A. The sensing layer 110 and the electrode pads 120 can be on the first surface 136A of the base structure 132.

The hole detection sensor 100 can include one or more contacts 140 on the second surface 136B of the base structure 132. In some implementations, the one or more contacts 140 include one or more solder balls, one or more micro-bumps, one or more bonding pads, or one or more copper pillars. The contacts 140 can be constructed from one or more conductive materials, e.g., copper (Cu), nickel (Ni), gold (Au), silver (Ag), tin-lead (SnPb) alloy, or any other suitable materials. In some implementations, the wiring board 130 is a BGA package, and each of the contacts 140 can be a solder ball made of the SnPb alloy. In some other implementations, the contacts 140 may not be solder balls. For example, the wiring board 130 is a land grid array (LGA) package, and each of the contacts 140 can include a flat bonding pad. In another example, the wiring board 130 is a pin grid array (PGA) package, and each of the contacts 140 includes a pin.

In some implementations, the contacts 140 are coupled to the electrode pads 120. Therefore, the electrical signals generated by the electrode pads 120 that correspond to the impedance value of the sensing layer 110 can be transmitted to another chip through the contacts 140. In some implementations, each contact 140 is coupled to a respective electrode pad 120. In some implementations, each contact 140 is coupled to two or more electrode pads 120. In some implementations, each electrode pad 120 is coupled to two or more contacts 140.

The contacts 140 can be coupled to electrode pads 120 using various techniques. In some implementations, as illustrated in FIG. 1A, the contacts 140 are coupled to the electrode pads 120 through interconnecting layers 134 inside the base structure 132. For example, as illustrated in FIG. 1A, the interconnecting layers 134 can include one or more layers of conductive lines 106, such as copper wires, and the like. The conductive lines 106 can be isolated from one another by the non-conductive material of the base structure 132. The conductive lines 106 on the different layers can be connected by conductive vias 108.

In some implementations, as illustrated in FIG. 1C, the contacts 140 are coupled to the corresponding electrode pads 120 through conductive wires 190. A contact 140 and an electrode pad 120 can form a pair, and each pair is connected through a single conductive wire 190. For example, one end of the conductive wire 190 is connected to the contact 140, while the other end of the conductive wire 190 is directly connected to the corresponding electrode pad 120. This approach may eliminate the need for an intermediate interconnecting structure. The conductive wires 190 can be made of copper (Cu), nickel (Ni), aluminum (Al), silver (Ag), gold (Au), or any other suitable materials. The conductive wires 190 can be routed within the base structure 132. Alternatively, at least part of the conductive wire 190 can be exposed on the second surface 136B of the base structure 132.

As noted above, the wiring board 130 can be a BGA package. With continued reference to FIG. 1C, in the wiring board 130, the contacts 140 can be arranged in a two-dimensional grid pattern across the second surface 136B of the wiring board 130. The grid pattern can include fine-pitch solder balls (e.g., contacts 140) and/or coarse-pitch sold balls. Fine-pitch solder pads may have smaller distances between them (e.g., 0.8 mm, 0.5 mm, or even finer), allowing for higher component density, while coarse-pitch solder pads may have larger distances between pads (e.g., 1.3 mm or more). In some examples, the grid pattern of the wiring board 130 can include fine-pitch solder balls. The grid pattern can be symmetric to evenly distribute mechanical forces during soldering process.

Returning to FIG. 1A, in some implementations, the hole detection sensor 100 includes a dielectric coating layer 160 covering the sensing layer 110. The dielectric coating layer 160 can include polyimide, epoxy, silicone, or any other suitable materials. The dielectric coating layer 160 may protect the sensing layer 110 from environmental factors (e.g., moisture, dust, contaminants). The dielectric coating layer 160 can also provide mechanical protection by preventing minor physical damage to the sensing layer 110, such as scratches, or other forms of wear during the normal operation of the hole detection sensor 100. With the dielectric coating layer 160, the sensing layer 110 may be invisible after assembly, making it more difficult for an attacker to bypass the sensing layer 110 during a tampering event.

In some implementations, the hole detection sensor 100 can include a polymer layer 180 between the sensing layer 110 and the wiring board 130. The polymer layer 180 can be placed on the first surface 136A of the base structure 132 and surrounded by the electrode pads 120. When the sensing layer 110 is placed on the electrode pads 120, the polymer layer 180 can be used to provide mechanical support to the sensing layer 110 to reduce the risk of bending or deformation.

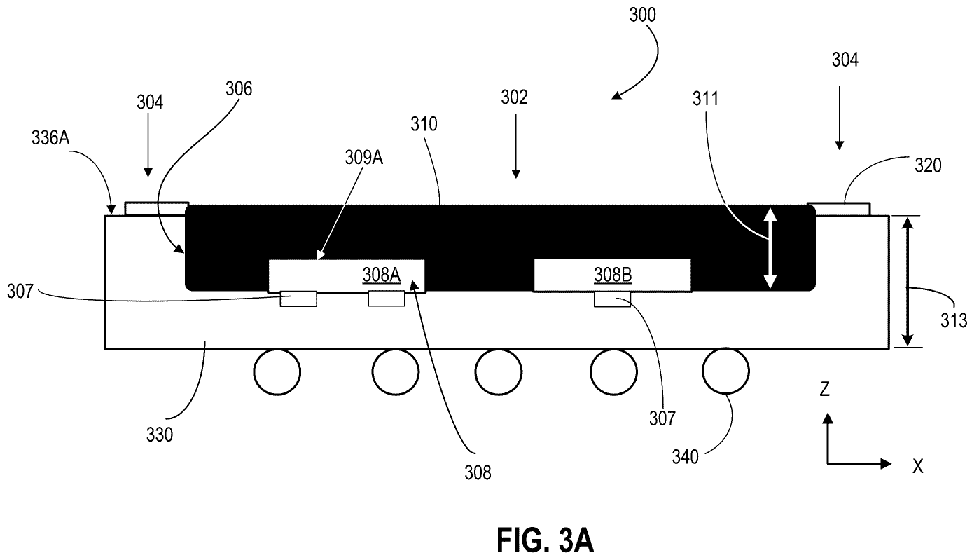

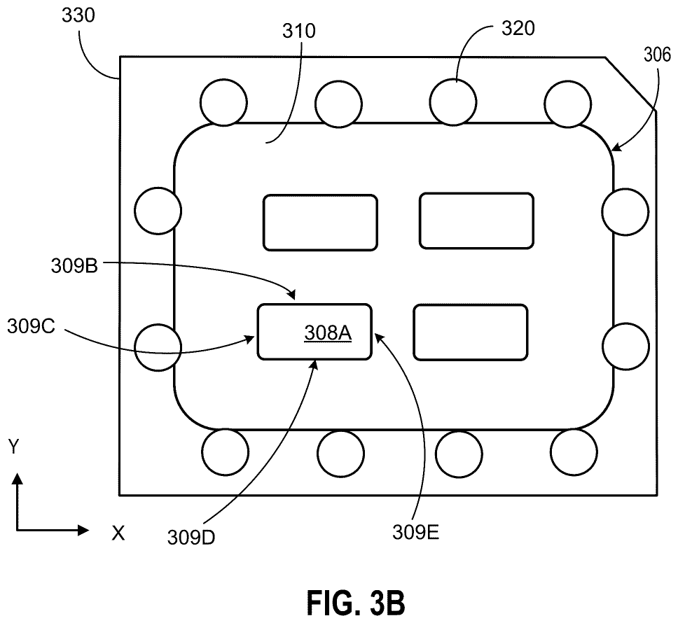

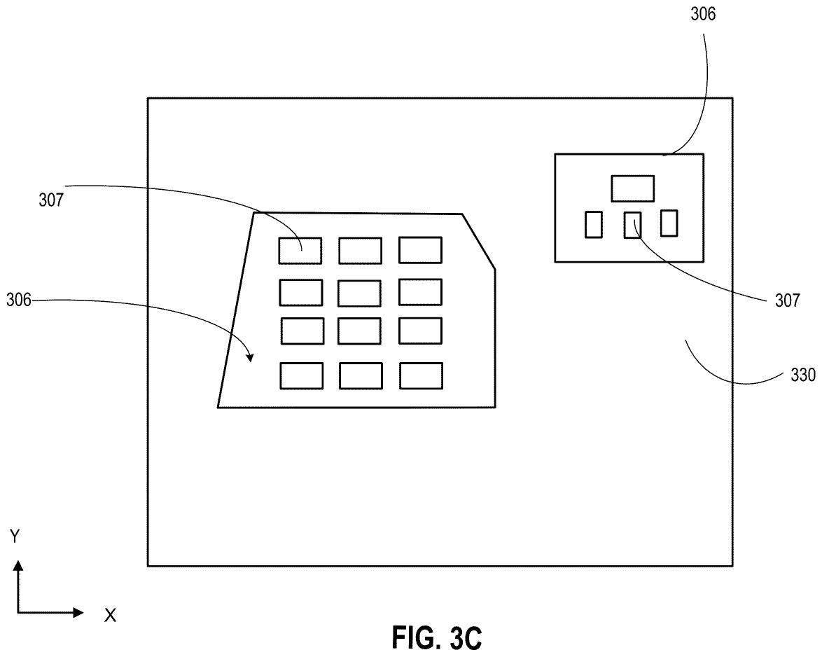

FIGS. 3A and 3B illustrate another example of a hole detection sensor 300. FIG. 3C illustrates an example of a wiring board with cavities. FIG. 3D illustrates examples of holes in the hole detection sensor 300. The hole detection sensor 300 differs from the hole detection sensor 100 of FIGS. 1A-1C primarily in that the sensing layer 310 in the hole detection sensor 300 is encapsulated into a cavity of the wiring board 330 and that the electrode pads 320 are surrounding the sensing layer 310. Most of components included in the hole detection sensor 300 described below and materials included in the components may be the same as or similar to those of the hole detection sensor 100 described above with reference to FIGS. 1A-2. Thus, for brevity, the following description will focus on the differences between two implementations, and redundant descriptions will be omitted.

As illustrated in FIG. 3A, in some implementations, the wiring board 330 includes an inner region 302 and a perimeter region 304 that surrounds the inner region 302. The inner region 302 includes a cavity 306. The cavity 306 can have a depth 311 along Z direction that is smaller than a height 313 of the wiring board 330 along Z direction. Therefore, the cavity 306 does not extend entirely through the wiring board 330. In some implementations, the depth 311 of the cavity 306 is about 30% to 90% of the height 313 of the wiring board 330. In plan view, the cavity 306 can have a regular shape (as shown in FIG. 3B), an irregular shape (as shown in FIG. 3C), or any other suitable shape. In some implementations, a size of the cavity 306 along a lateral direction (e.g., X and/or Y direction) is smaller than a size of the wiring board 330 along the same direction. In some implementations, the cavity 306 is located at or near a geometric center of the wiring board 330. In some implementations, the cavity 306 is located off-center. In some implementations, the cavity 306 is spaced apart from the perimeter of the wiring board 330 (e.g., the edges in X-Y plane) such that electrode pads 320 can be formed on the wiring board 330 between the cavity 306 and the perimeter of the wiring board 330. In some implementations, the wiring board 330 has two or more cavities 306, as illustrated in FIG. 3C. The two or more cavities 306 can have same or different sizes, shapes, and/or locations.

In some implementations, the sensing layer 310 is at least partially inside the cavity 306. The sensing layer 310 can be the sensing layer 200 of FIG. 2 that includes alternative CNT layers 220 and BNNT layers 210 encapsulated in an encapsulant layer 230. The sensing layer 310 can also be any other sensing layer described in the present disclosure. In some implementations, the sensing layer 310 substantially conforms to the shape of the cavity 306, resulting from an encapsulation process, as described in further details below in reference to FIG. 7.

In some implementations, the plurality of electrode pads 320 are on the perimeter region 304. Different from the hole detection sensor 100 of FIGS. 1A-1C where the electrode pads 120 are below the sensing layer 110, here, the electrode pads 320 surround the sensing layer 310 along lateral directions (e.g., X and/Y directions). Referring now to FIG. 3B, in plan view, the electrode pads 320 are in contact with the perimeter of the sensing layer 310. Similar to the electrode pads 120 in the hole detection sensor 100 of FIGS. 1A-1C, the electrode pads 320 can be arranged in a matrix pattern with at least one row and at least one column.

Referring to both FIGS. 3A and 3B, in some implementations, the sensing layer 310 encapsulates at least one structure 308 inside the cavity 306. The structure 308 can be positioned on a bottom surface of the cavity 306. In some implementations, the sensing layer 310 encapsulates a top side and at least one lateral side of the structure 308. For example, the sensing layer 310 can encapsulate a top side 309A of a first structure 308A (as shown in FIG. 3A) and four lateral sides 309B-309E of the first structure 308A (as shown in FIG. 3B). By encapsulating the structure 308 from at least two sides, the hole detection sensor 300 can be configured to detect a hole penetration along two or more directions. In some implementations, although not shown in FIG. 3A, the sensing layer 310 can entirely surround the structure 308, e.g., including the top side, a bottom side and all lateral sides. Therefore, the hole detection sensor 300 can detect the hole that extends into the sensing layer in any direction.

In some implementations, the at least one structure 308 includes a chip or a conductor. The chip can be any suitable chip that includes multiple active and passive components (e.g., transistors, diodes, resistors, and/or capacitors). The chip may process signals and perform computations. The chip can be a target chip of interest that stores sensitive information and is intended to be protected against a tampering event. The conductor can be a passive conductor, e.g., a conductive metal trace. While the conductor can conduct electrical signals or transmit signals, it may not process signals.

In the example implementations where the structures 308 include a chip (e.g., the first structure 308A), the chip can be flip-chip bonded to the bottom surface of the cavity 306. The bottom surface of the cavity 306 can expose one or more inner contact pads (e.g., inner contact pads 307 of FIGS. 3A and 3C) of the wiring board 330. These inner contact pads 307 can provide conductive terminals for signal transmissions between the chip and the wiring board 330. The chip can be bonded onto the inner contact pads 307 through solder balls, micro-balls, pins, or other suitable packaging methods.

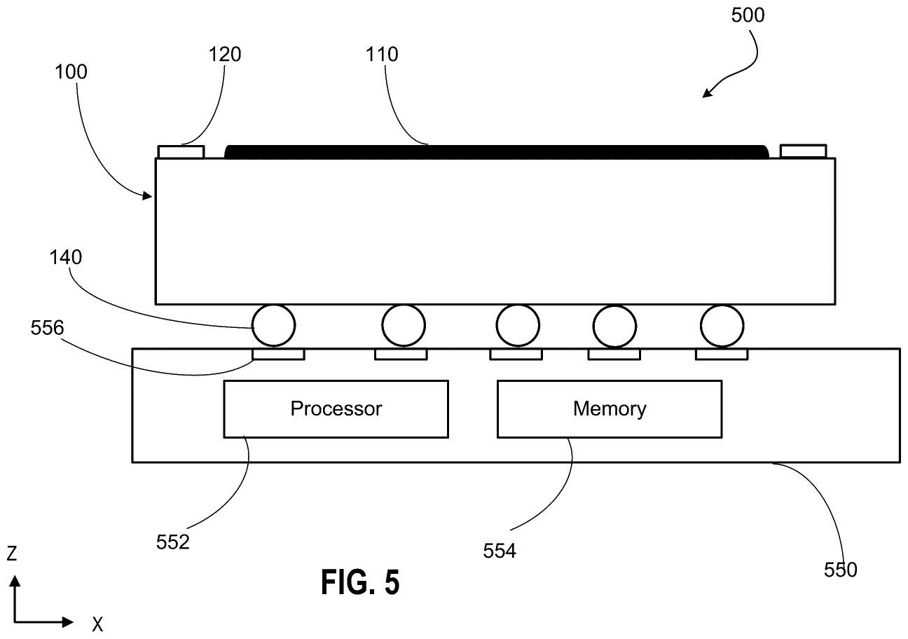

In some implementations, the inner contact pads 307 are coupled to the electrode pads 320 and/or contacts 340 using the techniques described above. For example, turning briefly to FIG. 1C, the inner contact pads 307 can be located in a center region of the wiring board 330. Each inner contact pad 307 can be coupled to a corresponding contact 140 through a conductive wire 190. In some examples, the hole detection sensors 100, 300 can be bonded on an external chip through the contacts 140, 340 (as shown in FIG. 5). Therefore, the inner contact pads 307 and the electrode pads 120, 320 can transmit electrical signals to the external chip through their corresponding contacts 140, 340.

Referring now to FIG. 3D, when a tampering event occurs, a hole 360 may form in the sensing layer 310. The hole 360 may penetrate completely through the sensing layer 310 or extends partially into the sensing layer 310. The hole detection sensor 300 can detect an impedance change of the sensing layer 310 due to the presence of the hole 360. In some examples, the hole detection sensor 300 can send an electrical signal to the chip to determine the presence, location and/or size of the hole 360. In response to the electrical signal, the chip may erase sensitive information or disable some functionality. By encapsulating the chip from at least two sides, the hole detection sensor 300 can detect holes 360 from any direction (e.g., X, Y and/or Z directions). For example, the hole detection sensor 300 can detect the first hole 360A that extends into the sensing layer 310 along X direction, and the second hole 360B that extends into the sensing layer 310 along Z direction.

Returning to FIG. 3A, in the example implementations where the structures 308 include a passive conductor (e.g., the second structure 308B), the conductor can be used as additional electrode pads for measuring the impedance value of the sensing layer 310. Similar to the electrode pads 320 that surround the sensing layer 310 on the first surface 336A of the wiring board 330, the passive conductor may be electrically connected to the sensing layer 310 and detect an impedance change when paired with any other electrode pad 320. The electrical signals that are measured by the passive conductor may be used to determine a depth 311 of the hole 360. In some implementations, the passive conductor can be the inner contact pads 307 of FIG. 3C. In some implementations, the passive conductors can protrude from the bottom surface of the cavity 306, as shown by the second structure 308B of FIG. 3A.

In the present example shown in FIGS. 3A and 3B, four structures 308 are included in the cavity 306, but the number of structures 308 is not limited thereto. For example, there can be 1, 2, 3, or 5 structures 308 inside the cavity 306. The four structures 308 can have different configurations. For example, two of the four structures 308 can be chips, while the other two structures 308 can be passive conductors.

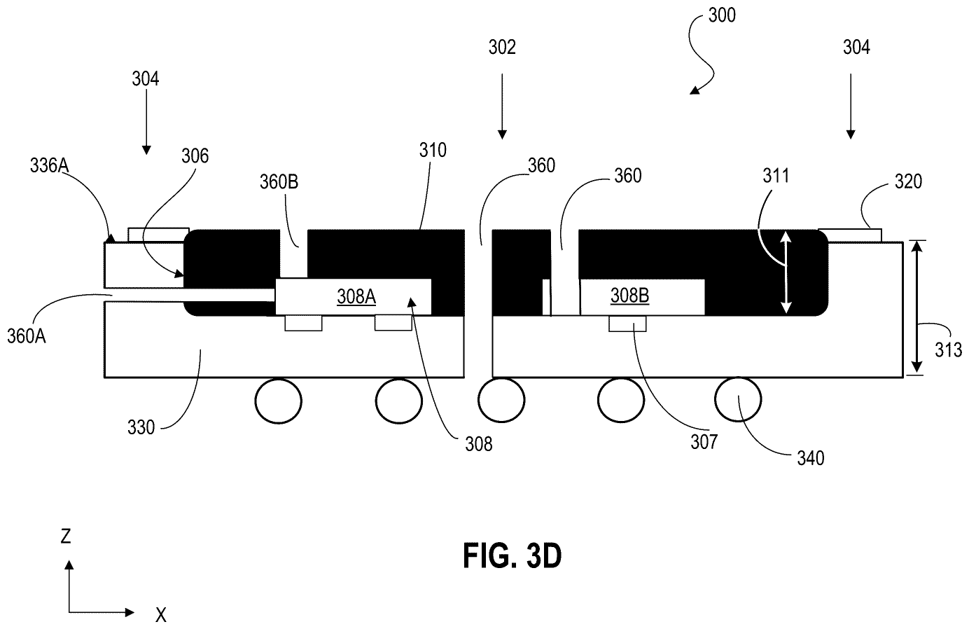

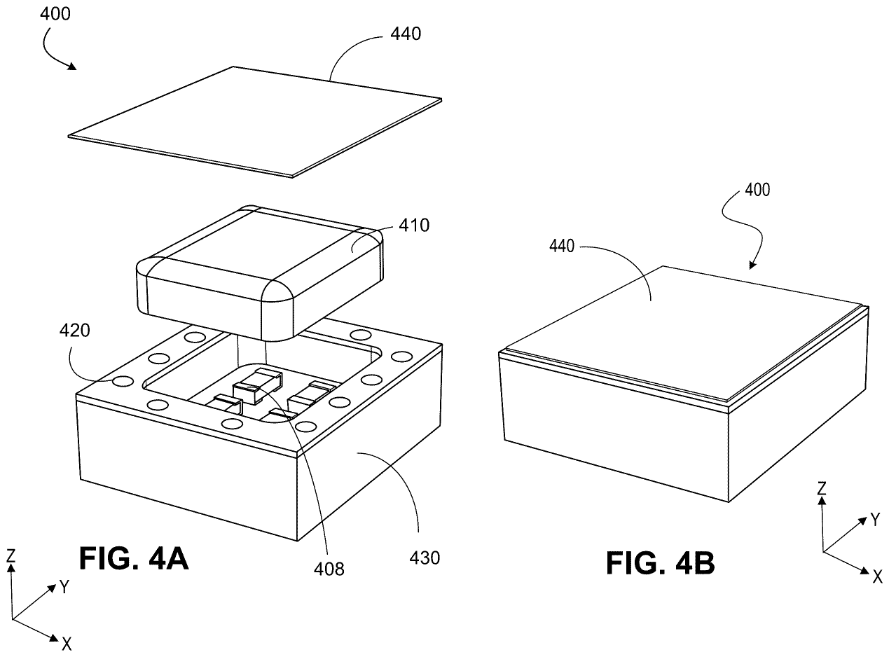

FIGS. 4A and 4B illustrate another example of a hole detection sensor 400. FIG. 4A illustrates an exploded view of the hole detection sensor 400. FIG. 4B illustrates an assembled view of the hole detection sensor. The hole detection sensor 400 has structures and component that are same or substantial similar to the hole detection sensor 100 of FIGS. 1A-1C and the hole detection sensor 400 of FIG. 3A-3C. For brevity, redundant descriptions will be omitted.

As illustrated in FIGS. 4A and 4B, the hole detection sensor 400 includes a first sensing layer 410 and a second sensing layer 440. The first sensing layer 410 can be the sensing layer 310 described above in reference to FIGS. 3A-3D, while the second sensing layer 440 can be the sensing layer 110 described above in reference to FIGS. 1A-2. The second sensing layer 440 can cover both the first sensing layer 410 and the plurality of electrode pads 420 that are arranged around the first sensing layer 410. In some implementations, the first sensing layer 410 can include alternative CNT layers and BNNT layers encapsulated in a polymer layer, while the second sensing layer 440 can be a CNT sheet. In some implementations, the first sensing layer 410 can include dispersed CNTs and BNNTs inside a polymer layer, while the second sensing layer 440 can be a doped BNNT sheet. In some implementations, both the first sensing layer 410 and the second sensing layer 440 have the same materials. For example, both sensing layers 410, 440 include alternative CNT layers and BNNT layers encapsulated in a polymer layer. However, the two sensing layers 410, 440 may have different size or shape.

In some implementations, an electrode pad 420 is coupled to either first sensing layer 410 or the second sensing layer 440. Therefore, the impedance value of the first and second sensing layers 410, 440 can be separately measured. In some implementations, an electrode pad 420 can be coupled to both first sensing layer 410 and second sensing layer 440. Therefore, the impedance value of the first and second sensing layers 410, 440 can be measured together.

Having two sensing layers in a hole detection sensor 400 may improve the effectiveness of the hole detection. For example, two sensing layers may provide redundancy. When one sensing layer fails to detect a hole or penetration, the other sensing layer may be used for detection. Additionally, with two sensing layers, the hole detection sensor 400 can be more sensitive to a wider range of penetration types and locations. For example, the first sensing layer 410 can be used to detect deeper or more complex penetrations, while the second sensing layer 440 can be used to detect superficial holes.

FIG. 5 illustrates an example of a device 500 with a hole detection sensor 100 stacked on a chip 550. The device 500 is shown as being implemented with the hole detection sensor 100 described with reference to FIGS. 1A-1C. However, the device 500 is useable with any of the implementation of the hole detection sensor 300, 400 shown in FIGS. 3A-4B.

In some implementations, the chip 550 includes one or more chip contacts 556 that are in contact with a corresponding contact 140 (also referred to as a sensor contact 140) of the hole detection sensor 100. For example, the sensor contacts 140 can be BGA solder balls, while the chip contacts 556 can be bonding pads. The BGA solder balls and the bonding pads can establish a communication terminal between the hole detection sensor 100 and the chip 550.

In some implementations, as noted above, the hole detection sensor 100 can be configured to generate a plurality of electrical signals. Each of the plurality of electrical signals can be corresponding to an impedance value of a respective portion of the sensing layer 110. The hole detection sensor 100 can be configured to transmit the plurality of electrical signals to the chip 550. For example, the electric signals can be transmitted from one or more electrode pads 120, through interconnecting layers (e.g., 134 of FIG. 1A) or conductive wires (e.g., 190 of FIG. 1C), to the sensor contacts 140, and then to the chip 550 through corresponding chip contacts 556.

In some implementations, the chip 550 is configured to receive the electrical signals from the hole detection sensor 100. The chip 550 can include at least one processor 552 and one or more memories 554 coupled to the at least one processor 552 and storing programming instructions for execution by the at least one processor 552 to perform operations described in this disclosure. For example, the chip 550 can be configured to determine, based on the plurality of electrical signals, the presence of the hole (e.g., 360 of FIG. 3D) in the sensing layer 110. In some implementations, to determine the presence of the hole in the sensing layer 110, the chip 550 can be configured to estimate, based on the electrical signal, the impedance value of the sensing layer 110. For example, the chip 550 can estimate the impedance value of the sensing layer 110 based on Ohm's law that describes the relationship between voltage, current, and resistance. In one example, the chip 550 can feed a current to the electrode pads 120 of the hole detection sensor 100 and determine a voltage across a corresponding portion of the sensing layer 110 based on the electrical signal. The chip 550 can then determine the impedance value of the corresponding portion of the sensing layer 110 based on Ohm's law.

In some implementations, the chip 550 can be further configured to compare the estimated impedance value with a reference value. In some examples, the reference value can be between several ohms to several kiloohms, or between hundreds of ohms to hundreds of kiloohms. In some implementations, the chip 550 is configured to, based on the estimated impedance value being above the reference value, determine the presence of the hole in the sensing layer 110. In some implementations, the chip 550 is configured to, based on the estimated impedance value being below the reference value, determine an absence of the hole in the sensing layer 110.

It is to be understood that the example methods described above for determining the presence of the hole by the chip 550 is not intended to be construed in a limiting sense. Other methods are also possible. In some implementations, the chip 550 can be configured to determine a size, a depth, and/or a location of the hole in the sensing layer 110 based on the electrical signals and locations of the electrode pads 120 that generate those signals.

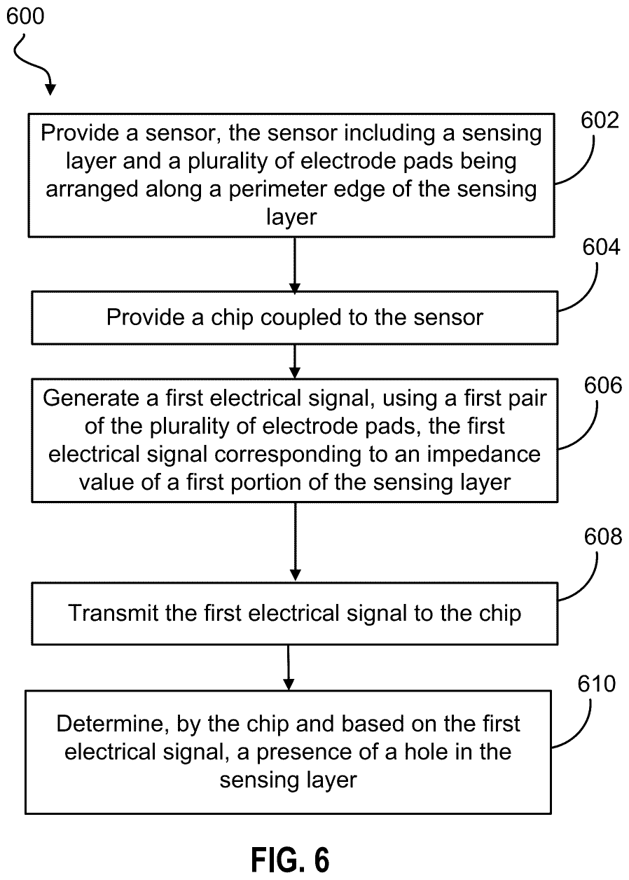

FIG. 6 illustrates a flow chart of an example of a method 600 to detect a hole using a device. The device can be the device 500 of FIG. 5. At step 602, a sensor is provided. The sensor includes a sensing layer and a plurality of electrode pads that are arranged along a perimeter of the sensing layer. The sensor can be the hole detection sensor 100 of FIGS. 1A-1C and 5, the hole detection sensor 300 of FIGS. 3A-3D, or the hole detection sensor 400 of FIGS. 4A-4B. The sensing layer can be the sensing layer 110 of FIGS. 1A, 1B and 5, the sensing layer 200 of FIG. 2, the sensing layer 310 of FIGS. 3A-3B, the first sensing layer 410 of FIG. 4A, or the second sensing layer 440 of FIGS. 4A and 4B. The electrode pads can be, e.g., the electrode pads 120 of FIGS. 1A-1C and 5, the electrode pads 320 of FIGS. 3A, 3B and 3D, or the electrode pads 420 of FIG. 4A.

At step 604, a chip is provided. The chip can be the chip 550 of FIG. 5. The chip can be coupled to the hole detection sensor through corresponding sensor contacts and chip contacts, as described above in reference to FIG. 5.

At step 606, a first electrical signal is generated using a first pair of the plurality of electrode pads. The first electrical signal is corresponding to an impedance value of a first portion of the sensing layer. Turning briefly to FIG. 1B, in an example, the first pair of electrode pads can include the second electrode pad 120-2 of FIG. 1B and the third electrode pad 120-3 of FIG. 1B. The second electrode pad 120-2 can be adjacent to the first edge 112A, while the third electrode 120-3 can be adjacent to the fourth edge 112D. The first edge 112A can be perpendicular to the fourth edge 112D. Correspondingly, the first portion of the sensing layer can refer to the upper-left quadrant 110-L of the sensing layer 110.

With continued reference to FIG. 1B, in some implementations, a second electrical signal is generated using a second pair of the plurality of electrode pads. The second electrical signal is corresponding to an impedance value of a second portion of the sensing layer. In an example, the second pair of electrode pads include the first electrode pad 120-1 and the fourth electrode pad 120-4. Correspondingly, the second portion of the sensing layer can refer to the left portion 110-L of the sensing layer 110.

Returning to FIG. 6, at step 608, the first electrical signal (and/or the second electrical signal) is transmitted to the chip, for example, from the electrode pads to the chip contacts.

At step 610, the presence of a hole in the sensing layer is determined, by the chip, based on the first electrical signal. In the implementations where multiple electrical signals are generated, the presence of the hole in the sensing layer can be determined based on the multiple electrical signals. In some implementations, as described above in reference to FIG. 5, determining the presence of the hole includes estimating the impedance value of the first portion of the sensing layer; and comparing the estimated impedance value with a reference value. In some implementations, the presence of the hole in the sensing layer can be determined based on the estimated impedance value being above the reference value. In some implementations, an absence of the hole in the sensing layer can be determined based on the estimated impedance value being below the reference value.

FIG. 7 illustrates a flow chart of an example of a method 700 to manufacture a hole detection sensor. The hole detection sensor can be the hole detection sensor 100 of FIGS. 1A-1C and 5, the hole detection sensor 300 of FIGS. 3A-3D, or the hole detection sensor 400 of FIGS. 4A-4B.

At step 702, a wiring board is provided. The wiring board can be, e.g., the wiring board 130 of FIGS. 1A, 1C and 5, the wiring board 330 of FIGS. 3A-3D, or the wiring board 430 of FIGS. 4A and 4B.

At step 704, one or more contacts can be formed on a first side of the wiring board. The contacts can be, e.g., the contacts 140 of FIGS. 1A, 1C and 5, or the contacts 340 of FIGS. 3A and 3D. The first side of the wiring board can be, e.g., the second side 130B of FIG. 1A.

At step 706, a sensing layer is formed. The sensing layer includes a plurality of BNNTs. The sensing layer is on a second side of the wiring board that is opposed to the first side. The sensing layer can be the sensing layer 110 of FIGS. 1A, 1B and 5, the sensing layer 200 of FIG. 2, the sensing layer 310 of FIGS. 3A-3B, the first sensing layer 410 of FIG. 4A, or the second sensing layer 440 of FIGS. 4A and 4B. The second side of the wiring board can be, e.g., the first side 130A of FIG. 1A.

In some implementations, the sensing layer includes a plurality of carbon nanotubes (CNTs). As described above in reference to FIG. 2, forming the sensing layer includes encapsulating at least one CNT layer and at least one BNNT layer into a polymer layer. The plurality of CNTs can be arranged in the at least one CNT layer, and the plurality of BNNTs can be arranged in the at least one BNNT layer. In some implementations, the at least one CNT layer and the at least one BNNT layer can be alternating with one another in the polymer layer.

In some implementations, forming the sensing layer includes dispersing the BNNTs and CNTs into a polymer matrix by ultrasonication (e.g., applying a high-frequency sound wave), shear mixing (e.g., using a high-speed mixer), solution mixing (e.g., dispersing in a solvent), or any other suitable techniques.

In some implementations, forming the sensing layer includes implanting dopants into the sensing layer. As noted above, the dopants can include silicon, iron, cobalt, nickel, molybdenum, titanium, and/or lithium but not limited thereto.

In some implementations, forming the sensing layer includes functionalizing the surfaces of CNTs and BNNTs to promote better interfacial bonding. Functionalizing the surfaces of CNTs and BNNTs can include chemical functionalization (e.g., introducing chemical groups to the surfaces of CNTs and BNNTs), physical functionalization (e.g., electrostatic functionalization by applying a charge to the surfaces), plasma treatment (e.g., exposing the CNTs or BNNTs to an ionized gas), or doping with metal ions (e.g., gold, silver, or copper) into the surfaces of the CNTs or BNNTs.

In some implementations, turning briefly to FIG. 3A, the method 700 include encapsulating the structures 308 in the cavity 306 of the wiring board. This encapsulating process can include (i) preparing an encapsulation material (e.g., dispersing the BNNTs and CNTs into a polymer matrix), (ii) bonding a chip of interest (e.g., structure 308 of FIG. 3A) onto the inner contact pads (e.g., 307 of FIG. 3C) of the cavity 306, and (iii) then applying the encapsulation material into the cavity 306 through injection molding or dispensing methods. Due to the flowability of the encapsulation material, the encapsulation material can easily fill the cavity 306 and adapt to the profiles of the structures 308. Subsequently, a curing process can be performed to harden the encapsulation material to form the sensing layer inside the cavity 306. Once cured, the sensing layer can retain its shape, providing protection to the structures 308 from multiple directions.

At step 708, a plurality of electrode pads are formed on the second side of the wiring board. The plurality of electrode pads are arranged along a perimeter of the sensing layer and coupled to the sensing layer. The electrode pads can be, e.g., the electrode pads 120 of FIGS. 1A-1C and 5, the electrode pad 320 of FIGS. 3A and 3B, or the electrode pads 420 of FIG. 4A.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A penetration detection sensor, comprising:
a sensing layer comprising a plurality of boron nitride nanotubes (BNNTs); and
a plurality of electrode pads being arranged along a perimeter of the sensing layer and coupled to the sensing layer,
wherein the sensor is configured to, using at least two of the plurality of electrode pads, generate an electrical signal corresponding to an impedance value of the sensing layer, and
wherein the impedance value is indicative of a structural integrity condition of the sensing layer.

2. The sensor of claim 1, wherein the sensing layer comprises a plurality of carbon nanotubes (CNTs).

3. The sensor of claim 1, wherein the sensing layer comprises conductive dopants.

4. The sensor of claim 2, wherein the plurality of BNNTs are arranged in at least one BNNT layer, the plurality of CNTs are arranged in at least one CNT layer, and the at least one BNNT layer and the at least one CNT layer are encapsulated in an encapsulant layer.

5. The sensor of claim 4, wherein the at least one BNNT layer and the at least one CNT layer alternate with one another in the encapsulant layer.

6. The sensor of claim 1, wherein the perimeter of the sensing layer comprises a plurality of edges, the plurality of edges including a first edge, a second edge, a third edge and a fourth edge, the first edge and the third edge being opposed to each other along a first direction, the second edge and the fourth edge being opposed to each other along a second direction,
wherein the plurality of electrode pads are along the first to fourth edges of the perimeter of the sensing layer.

7. The sensor of claim 1, wherein the structural integrity condition comprises at least one of a presence of a hole extending into the sensing layer, a crack, a mechanical strain, or a mechanical stress.

8. The sensor of claim 1, comprising:
a wiring board; and
one or more contacts on a first side of the wiring board, the one or more contacts being coupled to the plurality of electrode pads,
wherein the sensing layer and the plurality of electrode pads are on a second side of the wiring board that is opposite to the first side.

9. The sensor of claim 8, wherein the sensing layer is on the plurality of electrode pads.

10. The sensor of claim 8, wherein the second side of the wiring board comprises an inner region and a perimeter region that surrounds the inner region, and
wherein the inner region comprises a cavity, the sensing layer is inside the cavity and encapsulated within an encapsulant layer, and the plurality of electrode pads are on the perimeter region and surround the sensing layer.

11. The sensor of claim 10, wherein the encapsulant layer encapsulates a structure inside the cavity.

12. (canceled)

13. The sensor of claim 10, wherein the sensing layer is a first sensing layer, and
wherein the sensor comprises a second sensing layer, the second sensing layer comprising a plurality of BNNTs, the second sensing layer covering both the first sensing layer and the plurality of electrode pads, the plurality of electrode pads being coupled to the second sensing layer.

14. The sensor of claim 8, wherein the wiring board comprises an interconnecting layer, and the plurality of electrode pads are coupled to the one or more contacts through the interconnecting layer.

15. (canceled)

16. The sensor of claim 8, wherein the one or more contacts comprise one or more solder balls, one or more micro-bumps, one or more bonding pads, or one or more copper pillars.

17. The sensor of claim 1, wherein the sensor is configured to generate the electrical signal using a first electrode pad and a second electrode pad of the plurality of electrode pads, and
wherein the perimeter comprises a plurality of edges, the first electrode pad is adjacent to a first edge of the perimeter, the second electrode pad is adjacent to a second edge of the perimeter, and the first edge is perpendicular to the second edge.

18. The sensor of claim 8, wherein the sensor is configured to generate a plurality of electrical signals that includes the electric signal, each of the plurality of electrical signals is associated with an impedance value of a respective portion of the sensing layer, and
wherein the sensor is configured to transmit, through the one or more contacts, the plurality of electrical signals to a chip.

19.-43. (canceled)

44. A method of fabricating a hole detection sensor, comprising:
providing a wiring board;
forming one or more contacts on a first side of the wiring board;
forming a sensing layer comprising a plurality of boron nitride nanotubes (BNNTs), the sensing layer being on a second side of the wiring board that is opposed to the first side; and
forming a plurality of electrode pads on the second side of the wiring board, the plurality of electrode pads being arranged along a perimeter of the sensing layer and coupled to the sensing layer.

45. The method of claim 44, wherein the sensing layer comprises a plurality of carbon nanotubes (CNTs), and
wherein forming the sensing layer comprises:
encapsulating at least one CNT layer and at least one BNNT layer into a polymer layer, the at least one CNT layers comprising the plurality of CNTs, and the at least one BNNT comprising the plurality of BNNTs.

46. The method of claim 45, wherein the at least one CNT layer and the at least one BNNT layer alternate with one another.

47. The method of claim 44, wherein forming the sensing layer comprises:
implanting conductive dopants into the sensing layer.

48.-53. (canceled)
